(19) United States
(12) Patent Application Publication
(10) Pub. No.: US 2011/0147052 A1
(43) Pub. Date: Jun. 23, 2011

(54) POLYIMIDE FILM

(75) Inventor: Hak Gee JUNG, Suwon-si (KR)

(73) Assignee: Kolon Industries, Inc., Gwacheon-si (KR)

(21) Appl. No.: 13/037,839

(22) Filed: Mar. 1, 2011

Related U.S. Application Data
(63) Continuation of application No. 12/096,219, filed on Nov. 18, 2008, now abandoned.

(30) Foreign Application Priority Data
Dec. 5, 2005 (KR) 10-2005-0117550

(51) Int. Cl. B32B 27/34; B32B 7/06; C08G 73/10; H05K 1/00

(52) U.S. Cl. 174/254; 428/41.5; 528/340; 528/338

(57) ABSTRACT

Disclosed is a polyimide film for insulating material prepared by reacting an acid anhydride and diamine compounds comprising p-phenylenediamine. The polyimide film has excellent electric properties such as a coefficient of thermal expansion, an elongation, a intensity, a dielectric strength and a bulk resistance, and suitable for use in a TAB tape employing a polyimide film, and a flexible printed wiring board.

This is a continuation application of Ser. No. 12/096,219 (pending) filed Nov. 18, 2008, which is a National Stage application under 35 U.S.C. §371 of PCT/KR2006/005195 filed on Dec. 5, 2006, and which claims priority from Korean patent application No. 10-2005-0117550 filed on Dec. 5, 2005, all of which are incorporated herein by reference.

### TECHNICAL FIELD

The present invention relates to a novel polyimide film, specifically having a sufficient tensile modulus, a lower absorption rate, a lower coefficient of hydroscopic expansion, a lower coefficient of linear expansion, and a high dimensional stability, and applied to a insulating film of various electric/electronic devices comprising a flexible printed connection board, a semiconductor packaging, a magnetic recording film, and a hard disk suspension connection base.

### BACKGROUND ART

In general, a polyimide resin indicates a high heat resistance resin prepared in a manner that an aromatic tetracarboxylic acid or the derivatives thereof and an aromatic diamine or aromatic diisocyanate are solution-polymerized to form a polyamic acid derivative and then the polyamic acid derivative is subjected to imidization by cyclization and dehydrogenation at high temperature. The polyimide resin has various molecular structure depending on the kinds of the monomers employed in polymerization, and a pyromellitic dianhydride (PMDA) or 3,3′,4,4′-biphenyltetracarboxylic dianhydride (BPDA) as an aromatic tetracarboxylic dianhydride is generally used, and p-phenylenediamine (p-PDA), the m-phenylenediamine (m-PDA), 4,4′-oxydianiline (ODA), 4,4′-methylenedianiline (MDA), 2,2′-bisaminophenylhexafluoropropane (HFDA) and the like as an aromatic diamine are generally used as an aromatic diamine.

Most of polyimide resins are widely used as an insoluble and non-melting ultra high heat resistance resin in high end technology requiring heat resistance owing to their excellent thermal oxidation stability, thermal endurance (about 260° C. of usable temperature in long term, and 480° C. of usable temperature in short term), radiation resistance, low-temperature characteristics, chemical resistance and the like. But there are difficulties in applying polyimide resins to a field requiring transparency of a product due to the following disadvantages: First, a polyimide resin has a lower optical transmittance and shows a yellowish in the range of visible rays due to the high density of an aromatic ring within the polyimide resin. The second, it has a low hydroscopic property compared to other polymer films. The third, it has a high dielectric constant and a poor adhesive property.

Also, in case of the polyimide film used lately, it has a excellent flexibility in comparison with other films, hence it has been used within narrow spaces of a compact electric home appliance, a potable electric device requiring a thin circuit board, and a camera in a cut and folded form being facilitated as a flexible printed circuits board (named as FPC hereinafter). But, recently FPC requires more enhanced sliding and flexibility property as it has become widely used in driving parts of a flexible disk drive (FDD), hard disk drive (HDD), copy writer, printer and the like. FPC requires a resin film (named as a base film) as a base material. A polyimide film comprising a highly flexible polyimide in view of chemical structure in the purpose of enhancing sliding and flexural property is used as the base film.

However, because the high flexible polyimide, in general, has a high thermal expansibility, that is, has a high coefficient of hygroscopic expansion and linear expansion, a FPC employing the polyimide film as a base film may have a defect that a curling or twisting easily appear. Therefore, the polyimide film for the base film of the flexible printed connection board is required to have a high tensile modulus, a lower coefficient of hygroscopic expansion and a lower coefficient of linear expansion. On the other hand, if the resin film made of the polyimide with a lower coefficient of linear expansion is used as the base film, it is very brittle due to the lose of flexibility of film itself and the flexibility of the resulting FPC is lowered. In particular, a plate base film with a high dimensional stability has to be used as a flexible printed connect board of plasma display panel (PDP) because the plate base film has wider area than that in any other use.

As describe in the above, the polyimide prepared by condensation polymerizing pyromellitic dianhydride with 4,4′-oxydianiline has been used in the electric/electronic devices, because it can be used in the above devices due to the high heat resistance and electric insulation. And also, owing to the advantage of the high dimensional stability, the film made of the polyimide can be used in the flexible printed connection board.

In the meantime, an attempt that a tensile modulus may increase by providing 3-component based polyimide consisting of pyromellitic dianhydride, 4,4′-oxydianiline and p-phenylenediamine was performed. For example, the attempt may include the inventions in JP-A-60-210629, JP-A-64-16832, JP-A-64-16833, JP-A-64-16834, JP-A-1-131241 and JP-A-1-131242 (in the present specification, the term “JP-A” means “Not-examined and published patent application in Japan”.).

And also, an attempt to provide 4-components based polyimide having enhanced tensile modulus by adding 3,3′,4,4′-biphenyltetracarboxylic dianhydride (BPDA) to the above 3-components based polyimide was performed. For example, in JP-A-59-164382, and, JP-A-61-111359 describe the above 4-component based polyimide.

Furthermore, an attempt that the property of polyimide improves by adding the above monomers in the polymerizing process in an adjusted order has been reported, for example in JP-A-5-25273. Also, JP-A-63-189490, JP-A-3-60182, JP-A-9-77871, JP-A-10-36506, and JP-A-11-54862 describe use of an acid with similar structure to that of p-phenylene bis(trimellitic acid monoester anhydride).

### DISCLOSURE OF INVENTION

### Technical Problem

As described in the above, various studies for meeting the requirements have been performed as the requirements for the polyimide film used in the electric/electronic devices increase. For now, however, a polyimide film with excellent properties (for example, excellently high tensile modulus, lower hydroscopic property, lower coefficient of hygroscopic expansion, lower coefficient of linear expansion and high dimensional stability) has been never reported.

### Technical Solution

The present invention was made in consideration of the above described problems, and completed with the knowledge that a polyimide film prepared by reacting an acid anhydride comprising 4,4′-oxydiphthalic anhydride and pyromellitic dianhydride with an aromatic diamine comprising p-phenylenediamine and flexible diamine compounds has harmonization of thermal expansion, absorption and hygroscopic property and tensile modulus, and may avoid the occurrence of the curling and twisting.

It is an object of the invention to provide a polyimide film having a high tensile modulus and a dimensional stability, and lower absorption rate, coefficient of hygroscopic expansion, and coefficient of linear expansion.

The polyimide film to achieve the above object is produced from polyamic acid prepared by reacting an acid anhydride comprising a mixture of 4,4′-oxydiphthalic anhydride, and at least one acid anhydrides selected from the pyromellitic dianhydride alone or other aromatic tetracarboxylic dianhydride with an diamine compound comprising a mixture of p-phenylenediamine, and at least one diamine compound selected from diamine compounds in which ether, methylene group and the like exist in form of bonding group between each chain formed by bonding nitrogen atom in an amino group with carbon atom, or selected from the diamine compounds having a structure that each chain formed by bonding nitrogen atom in an amino group with carbon atom is not linear arranged.

The polyimide film according to the present invention may comprise 4,4′-oxydiphthalic anhydride of 10 mol % to 80 mol % to the amount of total acid anhydrides. Preferably, the amount of 4,4′-oxydiphthalic anhydride may be 20 mol % to 60 mol % to that of the total acid anhydrides.

The polyimide film of the present invention comprises p-phenylenediamine and 4,4′-diaminodiphenylmethane of diamine compounds.

Also, the other polyimide film of the present invention may comprise p-phenylenediamine, and 4,4′-oxydianiline of diamine compounds.

According to the present invention, p-phenylene diamine may be comprised in amount of 10 to 70 mol %, preferably 20 to 60 mol % to that of the diamine compounds.

And also, the polyimide film of the present invention has a coefficient of linear expansion of 6 to 30 ppm at 50 to 300° C., a tensile modulus of at least 2.0 GPa, a coefficient of hygroscopic expansion of 13 ppm or less.

The polyimide film of the present invention with adhesive layer and protective layer can be applied to TAB tape. And the present invention may comprise the TAB tape. And, the polyimide film with metal conductive layer on at least one side may be applied to a flexible printed circuits board.

### Advantageous Effects

The polyimide film of the present invention has the coefficient of linear expansion and the tensile modulus corresponding to disappearance of the curling or twisting and has the coefficient of hygroscopic expansion corresponding to disappearance of the curling or twisting due to the dimensional change by a moisture-absorption. In the result, the curling or twisting to happen during manufacturing process of the FPC or TAB tape used in various electronic devices and to be the cause of the mounting inferiority can be avoided effectively.

### BEST MODE FOR CARRYING OUT THE INVENTION

The present invention will be described in detail in the following.

Monomers Used for the Synthesis of the Polyimide

The polyimide film of the present invention uses a polyimide obtained by reacting mainly an aromatic diamine with an aromatic tetracarboxylic dianhydride to form a polyamic acid and imidizing the polyamic acid. Herein, the phrase polyamic acid reacted by mainly an aromatic diamine with an aromatic tetracarboxylic dianhydride means that the amount of an aromatic tetracarboxylic dianhydride is the greatest in that of acid anhydrides and on the other hand the amount of an aromatic diamine is the greatest in that of diamine compounds being raw material of the polyamic acid. In other word, according to the present invention, for polymerizing a polyamic acid an aromatic tetracarboxylic dianhydride is comprised as acid anhydrides, an aromatic diamine is comprised as diamine compounds, the above aromatic compounds may be preferably the greatest amount, and other acid anhydrides or diamine compounds may be used.

Hereafter acid anhydrides and diamine compounds that are monomers of polyamic acid are described in detail in the following.

Acid Anhydrides

For producing the polyimide film according to the present invention, 4,4′-oxydiphthalic anhydride may be used as acid anhydrides corresponding to the raw material of a polyamic acid.

The substantial content of 4,4′-oxydiphthalic anhydride is not limited in a specific range, but the content is 10 mol % to 80 mol %, preferably 20 mol % to 60 mol % of the total tetracarboxylic dianhydrides.

Within the above range of 4,4′-oxydiphthalic anhydride, it is possible for the coefficient of linear expansion and the tensile modulus to be harmonized, and as less than upper limit of the above range it is possible for the coefficient of hygroscopic expansion to be lowered by adjusting the amount.

According to the present invention, pyromellitic dianhydride alone, or a mixture of pyromellitic dianhydride and at least one compound selected from other aromatic tetracarboxylic dianhydride may be used in combination as an acid anhydride. The aromatic tetracarboxylic dianhydride may include 2,3,6,7-naphthalene tetracarboxylic dianhydride, 1,2,5,6-naphthalene tetracarboxylic dianhydride, 2,2′,3,3′-biphenyltetracarboxylic dianhydride, 2,2-bis(3,4-dicarboxyphenyl)propane dianhydride, 3,4,9,10-perylenetetracarboxylic dianhydride, bis(3,4-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxy phenyl)methane dianhydride, bis (3,4-dicarboxyphenyl)ethane dianhydride, oxydiphthalic anhydride, bis(3,4-dicarboxyphenyl)sulfone dianhydride, bisphenol A bis (trimellitic acid monoester anhydride), 3,3′,4,4′-benzophenonetetracarboxylic dianhydride and 3,3′,4,4′-biphenyltetracarboxylic dianhydride. And the above compounds may be used in alone or in combinations of at least two components. The content of pyromellitic dianhydride alone or the mixture of pyromellitic dianhydride and at least one component selected from other aromatic tetracarboxylic dianhydride is not limited in a specific range, but the amount of 20 mol % to 90 mol %, preferably 40 mol % to 80 mol % may be used to the amount of 100 mol % of the total aromatic tetracarboxylic di-anhydrides. In particular, the content of pyromellitic dianhydride may be preferably 30 mol % to 90 mol % to the amount of 100 mol % of the total aromatic tetracarboxylic dianhydrides.

Diamine Component

For producing the polyimide film according to the present invention, at least aromatic diamine may be used as a diamine compound corresponding to the raw material of a polyamic acid.

According to the present invention, the aromatic diamine compounds may preferably comprise both a linear diamine and a flexible diamine.

Herein, the term “the linear diamine” indicates diamine compounds that has not a flexible group in a main chain such as ether, methylene, isopropylidene, hexafluoroisopropylidene, carbonyl, sulfone or sulfide group, or has a structure that each chain formed by bonding nitrogen atom in an amino group with carbon atom is linear arranged. The example of the linear diamine may include p-phenylenediamine and the nucleic substituent thereof, benzidine and the nucleic substituent thereof and the like, but is not limited to the above compound. The linear diamine may be used in alone, or in proper combination of at least two compounds. Among the above compound, p-phenylene diamine may be preferably used. By using the above compounds, the polyimide film having a excellent workability, handling and harmonization of properties can be obtained.

And, the term “the flexible diamine” indicates the diamine compounds in which ether group, methylene group and the like exist in form of bonding group between each chain formed by bonding nitrogen atom in an amino group with carbon, or selected from diamine compounds having a structure that each chain formed by bonding nitrogen atom in an amino group with carbon is not linear.

In the above terms “a linear diamine” and “a flexible diamine,” the word “linear” means in general that the diamine compounds exist in parallel at 180 as represented in a stereo structure.

The examples of a flexible diamines may include 4,4′-oxydianiline, 1,3-bis(4-aminophenoxy)benzene, 1,3-bis(3-aminophenoxy)benzene, 4,4′-bis(3-aminophenoxy)biphenyl, 4,4′-bis(4-aminophenoxy)biphenyl, bis(4-(4-aminophenoxy)phenyl)sulfone, bis(4-(3-aminophenoxy)phenyl) sulfone, 4,4′-diaminodiphenylpropane, 4,4′-diaminodiphenylmethane, 4,4′-diaminodiphenylsulfide, 3,3′-diaminodiphenylsulfone, 4,4′-diaminodiphenylsulfone, 3,3′-oxydianiline, 3,4′-oxydianiline, 2,4′-oxydianiline, 4,4′-diaminodiphenyl diethylsilane, 4,4′-diaminodiphenyl silane, 4,4′-diaminodiphenylethyl phosphineoxide, 4,4′-diaminodiphenyl N-methylamine, 4,4′-diaminodiphenyl N-phenylamine, 1,3-diaminobenzene, 1,2-diaminobenzene, and the like, but is not limited to the above compounds. The flexible diamine may be used in alone or in proper combinations of at least two compounds. Among the above mentioned compounds, 4,4′-oxydianiline or 4,4′-diaminodiphenylmethane may be preferably used. By using the above compounds, the polyimide film having an excellent balance of various properties can be obtained. The amount of the linear diamine and flexible diamine selected from the above compounds are not limited to a specific range, but the linear diamine, in particular p-phenylenediamine may be preferably in the range of 10 mol % to 70 mol %, more preferably in the range of 20 mol % to 60 mol % in base of the total diamine compounds as 100 mol %.

Likewise, the flexible diamine may be preferably used in the range of 30 mol % to 90 mol %, more preferably in the range of 40 mol % to 90 mol % in base of the total aromatic diamine compounds as 100 mol %.

The distribution forms of the linear diamine and the flexible diamine in the polyimide molecules (polyamic acid molecules) are not limited in a specific one, but The distribution forms of them are distributed preferably in random. By such random distribution, a high tensile modulus can be compatible with a low coefficient of linear expansion with ease. Also, a diamine (other diamine) not corresponding to the aromatic diamine may be used depending on the property required by the polyimide film according to the present invention. The content of other diamine is not limited to a specific range.

Organic Solvent

An organic solvent used for producing a polyamic acid solution of the above mentioned acid anhydrides and aromatic diamine, namely used as a polymerizing solvent for polymerization of the polyamic acid is not limited in a specific solvent only if the solvent can dissolve the polyamic acid. The examples of the solvent may include N,N-dimethylformamide, N,N-dimethylacetamide, N-methyl-2-pyrrolidone, and the like. And among the above solvents, N,N-dimethylformamide or N,N-dimethylacetamide can be used preferably. The above solvent is used generally in alone, but the proper combination of at least two solvents may be used, if necessary. The composition of the polyamic solution is not limited in a specific mixing ratio, but the amount of the polyamic acid in the organic solvent may be preferably 5 wt % to 35 wt %, more preferably 10 wt % to 30 wt %. by the use of within the above range it is possible to obtain a proper molecular weight and solution viscosity.

Filler

A filler may be added to the polyimide film of the present invention to improve various properties such as a sliding property, thermal conductivity, conductivity, corona resistance, abrasion resistance, impact resistance, and the like.

The filler, the example of the filler may include silica, titanium oxide, alumina, silicon nitride, boron nitride, calcium hydrogen phosphate, calcium phosphate, mica, and the like, but is not limited to the above.

The diameter of filler may vary depending on the film characteristic to be modified and the kinds of filler to be added, is not limited to a specific amount, but the mean diameter may generally be 0.05 μm to 100 μm preferably 0.1 μm to 75 μm, more preferably 0.1 μm to 50 μm, most preferably 0.1 μm to 25 μm. In case of the above range of the diameter, the modification effect of the polyimide film may appear easily, and if the diameter is not larger than the above range, the mechanical property including the good surface property, the abrasion resistance, and the like can be easily obtained. Also, the amount of filler not limited to a specific amount may vary depending on the film characteristic to be modified and the diameter of filler. In general, the addition amount of the filler may be in the range of 0.01 to 100 weight parts, preferably 0.01 to 90 weight parts, and more preferably 0.02 to 80 parts to the 100 part of the polyimide.

The addition method of the filler is not limited to a specific manner, but the examples of the addition method may comprise to add the reaction solution before or on the polymerization, to mix the filler using 3 yarns roll after completion of the polyamic acid polymerization, to mix a dispersion solution containing the filler with the polyamic acid solution, and the like. Among the above methods, to mix a dispersion solution containing the filler with the polyamic acid solution, in particular just before making a film may be preferable. By the above method, the contamination of the manufacture line due to the filler may be made in the least. In case of preparing the dispersion solution containing the filler, it is preferable to use the same solvent as the polymerizing solvent of the polyamic acid. And also, a dispersant, a thickener and the like may be use to disperse and stabilize the state of the dispersion in the condition that the film property is not affected by the agents.

Polymerization of Polyamic Acid

The polymerization (synthesis) is not limited to a specific method, and therefore a well-known method may be used. The solution of polyamic acid (hereinafter named as the polyamic acid solution) may be prepared by dissolving an acid anhydrides and a diamine compound into an organic solvent resulting to the equal molar ratio (substantial equal molar ratio) and reacting them. The reaction condition is not limited to a specific one, but the temperature is preferably in range of −20° C. to 80° C., and the reaction time may be preferably in the range of 2 to 48 hours. And also, the reaction atmosphere may be preferably inert atmosphere such as argon, nitrogen, or the like.

In the above polymerization various polymerization method may be used depending on how to render a reaction of an acid anhydride and a diamine compound. The examples of the polymerization methods may include one of those represented as (a) to (e) in the following:

(a) An aromatic diamine is dissolved in an organic solvent, and an aromatic tetracarboxylic dianhydride reacts to polymerize substantially in equal molar amount to that of the aromatic diamine; (b) An aromatic tetracarboxylic dianhydride reacts with the aromatic diamine compound in the little molar amount in an organic solvent to obtain a prepolymer having acid anhydride groups at both terminals. Subsequently, an aromatic diamine compound reacts up to the point that the molar amount of an aromatic diamine compound reaches that of an aromatic tetracarboxylic dianhydride through the total process; (c) An aromatic tetracarboxylic dianhydride reacts with an aromatic diamine compound in the excessive molar amount into an organic solvent to obtain a prepolymer having amino groups at both terminals. Subsequently, an aromatic tetracarboxylic dianhydride reacts up to the point that the molar amount of an aromatic diamine compound reaches that of an aromatic diamine compound through the total process; (d) An aromatic tetracarboxylic dianhydride is dissolved and/or dispersed into an organic solvent, and subsequently an aromatic diamine compound reacts up to the point that the two compound amounts to substantially equal molar; (e) A mixture of an aromatic tetracarboxylic dianhydride and an aromatic diamine substantially in equal molar amount reacts.

Manufacture of Polyimide Film

The method for producing a polyimide film from the polyamic acid solution according to the present invention is not limited to a specific one, and therefore a well-known method may be employed. The examples of the imidization method may include a thermal imidization method and a chemical imidization method, but the chemical imidization method may be preferably employed.

In the chemical imidization method, the dehydrating agent represented as an acid anhydride such as the acetic anhydride and the like, and imidization catalyst represented as the tertiary amines such as an isoquinoline, β-picoline, pyridine, and the like is acted in a polyamic acid solution. The thermal imidization method may be used in combination of the chemical imidization method. The heating condition may vary depending on the kinds of a polyamic acid, the thickness of film, and the like. By the above method, a polyimide film having an excellent thermal dimensional stability, mechanical strength and the like can be obtained.

The exemplary illustrations of the method for producing the polyimide film according to the present invention will be explained in detail, not limiting the scope of the present invention. The method for producing a polyimide film may include processes in the following: 1) a process for preparing a polyamic acid solution by reacting an aromatic diamine with a tetracarboxylic dianhydride in an organic solvent; 2) a process for adjusting the solution viscosity by adding a tetracarboxylic dianhydride to the prepared polyamic acid solution; 3) a process for proceeding the chemical imidization by adding a cyclization/dehydration catalyst to the polyamic acid solution; 4) a process for casting film-making doping solution containing the polyamic acid solution on the substrate such as glass plate, aluminum foil, circulation stainless belt, stainless drum, and the like; 5) a process for preparing a polyamic acid film (hereafter named as gel-film) by peeling off compound obtained through heating the film-making doping solution on the substrate at 80° C. to 200° C., preferably 100° C. to 180° C. to partly cure and/or dry with activating the dehydrating agent and the imidization catalyst and peeling off the gel-film from the substrate; and 6) a process for imidization of the residual amic acid by heating the gel-film, and drying. dehydration In the above process, it is preferable to heat finally for 5 to 400 seconds at the temperature of 250° C. to 550° C. If the temperature is higher that the above upper temperature limit and/or the time is longer than the upper interval limit, then heat-degradation may occur. On the other hand, if the temperature is lower than the lower temperature limit and/or the time is shorter than the lower interval limit, then the required effect may not be represented. The thickness of the obtained polyimide film is not limited to a specific one, but the thickness of the film, in particular for a base film of a TAB tape or FPC, may be 5 μm to 250 μm, preferably 10 μm to 100 μm.

Property of Polyimide Film

The polyimide film comprises the polyimide prepared by reacting a tetracarboxylic dianhydride with an aromatic diamine to form a polyamic acid. Of these compounds, a tetracarboxylic dianhydride may comprise with 4,4′-oxydiphthalic anhydride and pyromellitic dianhydride, and an aromatic diamine may comprise p-phenylenediamine and a flexible diamine, and the polyimide film obtained from these compounds may has following properties by adjusting the amount of compounds.

Condition A: an average coefficient of linear expansion at the temperature of 50 to 300° C. is 6 to 30 ppm/° C.

Condition B: a tensile modulus of at least 2.0 GPa.

Condition C: a coefficient of hygroscopic expansion of 13 ppm or less.

If the polyimide film meets the above condition A, the generation of curling or twisting in FPC or FCCL may be prevented. Hence, a polyimide having a high flexibility and a high coefficient of linear expansion in which range neither curling nor twisting occurs can be obtained. And also, the average coefficient of linear expansion of the polyimide film at the temperature of 50 to 300° C. may be 6 to 26 ppm/° C., preferably 6 to 20 ppm/° C. Also, if the polyimide film meets condition B, the dimensional change in roll to roll process, and further the curling or twisting of the film in FPC or FCCL may be prevented. The tensile modulus of the polyimide film may be 3.0 GPa to 8.0 GPa, preferably 3.0 GPa to 6.0 GPa. If the polyimide film meets condition C, the dimensional change by the internal stress between copper foils due to a hygroscopic expansion may be prevented. The coefficient of hygroscopic expansion of the polyimide film may be 12 ppm or less, preferably 10 ppm or less. By meeting the above three conditions, the polyimide film of the present invention has both a thermal expansion property and a tensile modulus wherein neither curling nor twisting occurs, and simultaneously it is possible to decrease the absorption and hygroscopic property. Hence, the polyimide that has neither the curling nor twisting due to the dimensional change by the hygroscopic property can be obtained.

The specific measuring method of the tensile modulus, the coefficient of thermal expansion, and the coefficient of hygroscopic expansion for the obtained polyimide is described in the following.

(1) Tensile Modulus Measurement

Tensile modulus of the polyimide film measured by the ASTM D882.

(2) Measurement of a Coefficient of Thermal Expansion

The average coefficient of linear expansion (CTE) in the range of 50° C. to 300° C. was performed using Q400 made by TA Co. Ltd. The sample was set up as a specimen in 4 mm width and 10 mm length, and then 5 g weight was loaded. The temperature of the specimen was raised up to 300° C. from 30° C., and then the thermal expansion was measured in the interval of 50° C. to 100° C., 100° C. to 200° C., and 200 to 300° C., and the average of each interval value was calculated.

(3) Measurement of a Coefficient of Hygroscopic Expansion (CHE)

The test film placed in an environmental tester for 24 hours at 25° C. and 50% relative humidity, and then the film length (L1) was measured. And then the test film placed in the same environmental tester for 48 hours at 35° C. and 90% relative humidity to measure the film length (L2), and a coefficient of hygroscopic expansion was estimated as the following equation.

Coefficient of hygroscopic expansion (ppm)=(L1−L2)÷L1÷(90−50)×10⁶

Manufacture of TAB Tape

A TAB tape was manufactured from the polyimide film of the present invention in the following manner, and the curling amount was measured. An adhesives solution was prepared by adding the following components to a toluene/methyl ethyl ketone 4/6 mixture solution, resulting to 25 parts:

Polyamide resin (Plata bond Nipol 1072 made by Nippon Rilsan company) 50 parts;

Bisphenol A-type epoxy resin (Epicoat 828 made by Ukashell Epoxy corp.) 20 parts;

Epicoat 834 10 parts;

Epicoat 5050 70 parts;

4,4′-DDS 8 parts;

Al(OH)₃ 20 parts; and

KBM-403 as dispersant.

The adhesives was coated on the polyimide film of 25 μm thickness to be dried thickness of 15 μm to 20 μm, and subsequently dried at 150° C. for 2 minutes. The obtained polyimide film attached by the adhesives was cut to be 35 mm width. After the PET film of 26 mm width was joined on the central part of the polyimide film coated/dried with adhesives, the resultant was compressed with 2 kg/cm² pressure at 90° C. The PET film was peeled off, and then RD copper foil of 18 μm thickness was adhered by roll laminating method at 165° C., and 2 kg/cm² pressure (TAB tape without etching) on the side of polyimide film where the PET film was peeled off to make “tape attached copper” was manufactured. After curing of the adhesives, “tape completely etched copper” was obtained by removing completely the copper foil by etching.

The curling amount of each obtained tape was measured in the following manner.

Measurement of Curling Amount

The curling amount of the TAB tape obtained through the above process was measured from the samples by cutting the TAB tape 40 mm length×35 mm width. After the samples was placed for 72 hours at 23° C. and 60% relative humidity, and the samples was accurately located to measure the rising height to the surface at the four corners. The curling value of the four corners was averaged.

### Mode for the Invention

The present invention will be described in detail with examples and comparisons in the following, not limiting the scope of the present invention.

### EXAMPLE 1

11.8962 g of 4,4′-diaminodiphenylmethane (MDA), and 4.3256 g of p-phenylenediamine (PDA) were dissolved in 203.729 g of N,N-dimethylformamide (DMF) and maintained at 0° C. Then 15.511 g of 4,4′-oxydiphthalic anhydride (ODPA) was slowly added to the solution and stirred for 1 hour to dissolve ODPA completely. 6.4446 g of 3,3′,4,4′-benzophenone tetracarboxylic dianhydride (BTDA) was slowly added to the solution, and stirred for 1 hour to completely dissolve. Subsequently 6.5436 g of pyromellitic dianhydride (PMDA) was further added the solution and stirred for 1 hour to obtain a polyamic acid solution having the properties such as a viscosity of 2500 poise at 23° C. and 18.0 wt % of solid content. The mol % of the added monomers is shown in the following table 1.

A predetermined amount of filler in range of 0.01 to 10 weight ratio to the obtained solution weight was dispersed into the solution, stirred and then degasing for 1 hour using a vacuum pump to cool 0° C. Then, a hardening agent consisting of 11.4 g of acetic anhydride, 4.8 g of isoquinoline, and 33.8 g of DMF was mixed with 100 g of the obtained polyamic acid solution and the mixture was cast over the stainless steel board. The aluminum foil coated with the polyamic acid solution was heated for 300 seconds at 100° C. to produce a gel-film, and the detached edge parts of the film was fixed at a frame after being peeled off from the aluminum foil. The fixed film was heated for 30 to 240 seconds at 150° C., 250° C., 350° C., and 450° C. and further heat-treated with a far infrared rays oven for 30 to 180 seconds.

A TAB tape was manufactured using the obtained polyimide film of 25 μm in the above mentioned manner.

The tensile modulus, the mean coefficient of linear expansion, the coefficient of hygroscopic expansion of the polyimide film and the curling amount of the TAB tape for “tape attached copper” and “tape completely etched copper” were measured. The molar ratio of monomers and the properties of the polyimide film and TAB tape were shown in table 1 and 2 in the following.

### EXAMPLE 2

9.9135 g of MDA and 5.407 g of PDA were dissolved into 198.5288 g of DMF to be maintained at 0° C. Then 21.7154 g of ODPA was slowly added to the solution and stirred for 1 hour to completely dissolve ODPA. 6.5436 g of PMDA was further added into the resultant solution and stirred for 1 hour to form the polyamic acid solution having the properties such as a viscosity of 3100 poise at 23° C. and 18.0 wt % of solid content. The mol % of the added monomers is shown in table 1 in the following. A polyimide film of 25 μm thickness and TAB tape were manufactured by the same method as example 1 excepting using the above obtained polyamic acid solution, and the mol % of the monomers and the properties of the polyimide film and TAB tape are shown in table 1 and 2 in the following.

In the following <example 3> to <example 15>, polyimide films of 25 μm thickness and TAB tape were manufactured by the same manner as that of <example 1> except that each polyamic acid prepared by each example was used, and mol % of the monomers of each example and the properties of each polyimide film and TAB tape are shown in table 1 and 2 in the following.

### EXAMPLE 3

10.9 g of MDA and 4.8663 g of PDA were dissolved into 199.2985 g of DMF to be maintained at 0° C. Then 15.511 g of ODPA was slowly added to the solution and stirred for 1 hour to completely dissolve ODPA. 4.83345 g of BTDA was slowly added to the solution and stirred for 1 hour to completely dissolve. 7.6377 g of PMDA was further added into the resultant solution and stirred for 1 hour to form the polyamic acid solution having the properties such as a viscosity of 2700 poise at 23° C. and 18.0 wt % of solid content. And the mol % of the monomers and the properties of the polyimide film and TAB tape are shown in table 1 and 2 in the following.

### EXAMPLE 4

9.9135 g of MDA, and 5.407 g of PDA were dissolved into 199.6231 g of DMF to be maintained at 0° C. Then 15.511 g of ODPA was slowly added the solution and stirred for 1 hour to completely dissolve ODPA. 6.4446 g of BTDA was slowly added to the solution and stirred for 1 hour to completely dissolve. 6.5436 g of PMDA was further added into the resultant solution and stirred for 1 hour to form the polyamic acid solution having the properties such as a viscosity of 2600 poise at 23° C. and 18.0 wt % of solid content. And the mol % of the monomers and the properties of the polyimide film and TAB tape are shown in table 1 and 2 in the following.

### EXAMPLE 5

11.8962 g of MDA and 4.3256 g of PDA were dissolved into 204.8232 g of DMF to be maintained at 0° C. Then ODPA 9.3066 g was slowly added to the solution and stirred for 1 hour to completely dissolve ODPA. 12.8892 g of BTDA was slowly added to the solution and stirred for 1 hour to completely dissolve. 6.5436 g of PMDA was further added into the resultant solution and stirred for 1 hour to form the polyamic acid solution having the properties such as a viscosity of 2400 poise at 23° C. and 18.0 wt % of solid content. And the mol % of the monomers and the properties of the polyimide film and TAB tape are shown in table 1 and 2 in the following.

### EXAMPLE 6

12.88755 g of MDA and 3.7849 g of PDA were dissolved into 207.4233 g of DMF to be maintained at 0° C. Then 6.2044 g of ODPA was slowly added to the solution and stirred for 1 hour to completely dissolve ODPA. 16.1115 g of BTDA was slowly added to the solution and stirred for 1 hour to completely dissolve. 6.5436 g of PMDA was further added into the resultant solution and stirred for 1 hour to form the polyamic acid solution having the properties such as a viscosity of 2200 poise at 23° C. and 18.0 wt % of solid content. And the mol % of the monomers and the properties of the polyimide film and TAB tape are shown in table 1 and 2 in the following.

### EXAMPLE 7

9.9135 g of MDA and 5.407 g of PDA were dissolved into 198.1653 g of DMF to be maintained at 0° C. Then 9.3066 g of ODPA was slowly added to the solution and stirred for 1 hour to completely dissolve ODPA. 6.4446 g of BTDA was slowly added to the solution and stirred for 1 hour to completely dissolve. 5.8844 g of 3,3′,4,4′-biphenyltetracarboxylic dianhydride (BPDA) was slowly added to the solution and stirred to completely dissolve BPDA. 6.5436 g of PMDA was further added into the resultant solution and stirred for 1 hour to form the polyamic acid solution having the properties such as a viscosity of 2300 poise at 23° C. and 18.0 wt % of solid content. And the mol % of the monomers and the properties of the polyimide film and TAB tape are shown in table 1 and 2 in the following.

### EXAMPLE 8

15.8616 g of MDA and 2.1628 g of PDA were dissolved into 185.6726 g of DMF to be maintained at 0° C. Then 3.1022 g of ODPA was slowly added the solution and stirred for 1 hour to completely dissolve ODPA. 19.6308 g of PMDA was further added into the resultant solution and stirred for 1 hour to form the polyamic acid solution having the properties such as a viscosity of 2600 poise at 23° C. and 18.0 wt % of solid content. And the mol % of the monomers and the properties of the polyimide film and TAB tape are shown in table 1 and 2 in the following.

### EXAMPLE 9

18.0216 g of 4,4′-oxydianiline(ODA) and 1.0814 g of PDA were dissolved into 194.7819 g of DMF to be maintained at 0° C. 6.2044 g of ODPA was slowly added the solution and stirred for 1 hour to completely dissolve ODPA. 17.4496 g of PMDA was further added into the resultant solution and stirred for 1 hour to form the polyamic acid solution having the properties such as a viscosity of 2600 poise at 23° C. and 18.0 wt % of solid content. And the mol % of the monomers and the properties of the polyimide film and TAB tape are shown in table 1 and 2 in the following.

### EXAMPLE 10

16.0192 g of ODA and 2.1628 g of PDA were dissolved into 188.4884 g of DMF to be maintained at 0° C. Then 4.6533 g of ODPA was slowly added the solution and stirred for 1 hour to completely dissolve ODPA. 18.5402 g of PMDA was further added into the resultant solution and stirred for 1 hour to form the polyamic acid solution having the properties such as a viscosity of 2800 poise at 23° C. and 18.0 wt % of solid content. And the mol % of the monomers and the properties of the polyimide film and TAB tape are shown in table 1 and 2 in the following.

### EXAMPLE 11

15.018 g of ODA and 2.7035 g of PDA were dissolved into 184.2927 g of DMF to be maintained at 0° C. Then 3.1022 g of ODPA was slowly added the solution and stirred for 1 hour to completely dissolve ODPA. 19.6308 g of PMDA was further added into the resultant solution and stirred for 1 hour to form the polyamic acid solution having the properties such as a viscosity of 2700 poise at 23° C. and 18.0 wt % of solid content. And the mol % of the monomers and the properties of the polyimide film and TAB tape are shown in table 1 and 2 in the following.

### EXAMPLE 12

14.0168 g of ODA and 3.2442 g of PDA were dissolved into 203.7203 g of DMF to be maintained at 0° C. Then 15.511 g of ODPA was slowly added the solution and stirred for 1 hour to completely dissolve ODPA. 3.2223 g of BTDA was slowly added the solution and stirred for 1 hour to completely dissolve BTDA. 8.7248 g of PMDA was further added into the resultant solution and stirred for 1 hour to form the polyamic acid solution having the properties such as a viscosity of 2400 poise at 23° C. and 18.0 wt % of solid content. And the mol % of the monomers and the properties of the polyimide film and TAB tape are shown in table 1 and 2 in the following.

### EXAMPLE 13

12.0144 g of ODA and 4.3256 g of PDA were dissolved into 184.2927 g of DMF to be maintained at 0° C. Then 7.7555 g of ODPA was slowly added the solution and stirred for 1 hour to completely dissolve ODPA. 16.359 g of PMDA was further added into the resultant solution stirring for 1 hour to form the polyamic acid solution having the properties such as a viscosity of 2500 poise at 23° C. and 18.0 wt % of solid content. And the mol % of the monomers and the properties of the polyimide film and TAB tape are shown in table 1 and 2 in the following.

### EXAMPLE 14

10.012 g of ODA and 5.407 g of PDA were dissolved into 191.6805 g of DMF to be maintained at 0° C. Then 9.3066 g of ODPA was slowly added the solution and stirred for 1 hour to completely dissolve ODPA. 6.4446 g of BTDA was slowly added the solution and stirred for 1 hour to completely dissolve BTDA. 10.906 g of PMDA was further added into the resultant solution and stirred for 1 hour to form the polyamic acid solution having the properties such as a viscosity of 2200 poise at 23° C. and 18.0 wt % of solid content. And the mol % of the monomers and the properties of the polyimide film and TAB tape are shown in table 1 and 2 in the following.

### EXAMPLE 15

8.0096 g of ODA and 6.4884 g of PDA were dissolved into 182.1949 g of DMF to be maintained at 0° C. Then 12.4088 g of ODPA was slowly added the solution and stirred for 1 hour to completely dissolve ODPA. 13.0872 g of PMDA was further added into the resultant solution and stirred for 1 hour to form the polyamic acid solution having the properties such as a viscosity of 2100 poise at 23° C. and 18.0 wt % of solid content. And the mol % of the monomers and the properties of the polyimide film and TAB tape are shown in table 1 and 2 in the following.

TABLE 1

| | Monomer composition (mol %) | | | | | | |
|---|---|---|---|---|---|---|---|
| | Diamine compound | | | | | | |
| | (mol %) | | | Acid anhydrides (mol %) | | | |
| Exams. | MDA | PDA | ODA | ODPA | PMDA | BTDA | BPDA |
| 1 | 60 | 40 | — | 50 | 30 | 20 | — |
| 2 | 50 | 50 | — | 70 | 30 | — | — |
| 3 | 55 | 45 | — | 50 | 35 | 15 | — |
| 4 | 50 | 50 | — | 50 | 30 | 20 | — |
| 5 | 60 | 40 | — | 30 | 30 | 40 | — |
| 6 | 65 | 35 | — | 20 | 30 | 50 | — |
| 7 | 50 | 50 | — | 30 | 30 | 20 | 20 |
| 8 | 80 | 20 | — | 10 | 90 | — | — |
| 9 | — | 10 | 90 | 20 | 80 | — | — |
| 10 | — | 20 | 80 | 15 | 85 | — | — |
| 11 | — | 25 | 75 | 10 | 90 | — | — |
| 12 | — | 30 | 70 | 50 | 40 | 10 | — |
| 13 | — | 40 | 60 | 25 | 75 | — | — |
| 14 | — | 50 | 50 | 30 | 50 | 20 | — |
| 15 | — | 60 | 40 | 40 | 60 | — | — |

(Notes)
MDA: 4,4′-diaminodiphenylmethane,
PDA: p-phenylenediamine
ODA: 4,4′-oxydianiline,
ODPA: 4,4′-oxydiphthalic anhydride
PMDA: pyromellitic dianhydride
BTDA: 3,3′,4,4′-benzophenone tetracarboxylic dianhydride.
BPDA: 3,3′,4,4′-biphenyltetracarboxylic dianhydride

TABLE 2

| | Result | | | | | | |
|---|---|---|---|---|---|---|---|
| | Tensile | | | | | Curling (mm) | |
| | modulus | CTE (ppm) | | | CHE | Copper | Completely |
| Exams. | (GPa) | 50-100° C. | 100-200° C. | 200-300° C. | (ppm) | Attached | Etched |
| 1 | 5.5 | 8 | 13 | 29 | 9 | −2.1 | 2.0 |
| 2 | 6.0 | 6 | 12 | 26 | 11 | −1.9 | 1.4 |
| 3 | 5.6 | 7 | 13 | 27 | 12 | −1.7 | 1.6 |
| 4 | 6.1 | 8 | 14 | 26 | 9 | −1.9 | 1.2 |
| 5 | 5.5 | 8 | 16 | 27 | 10 | −2.4 | 1.8 |
| 6 | 5.5 | 9 | 15 | 25 | 7 | −2.3 | 2.0 |
| 7 | 5.4 | 8 | 15 | 24 | 9 | −1.8 | 1.9 |
| 8 | 7.1 | 7 | 12 | 26 | 7 | −2.0 | 1.1 |
| 9 | 7.5 | 6 | 12 | 24 | 6 | −2.4 | 1.0 |
| 10 | 7.2 | 7 | 13 | 26 | 7 | −2.3 | 1.1 |
| 11 | 7.7 | 6 | 12 | 24 | 6 | −2.4 | 1.0 |
| 12 | 6.4 | 8 | 13 | 28 | 10 | −2.0 | 1.5 |
| 13 | 6.5 | 9 | 14 | 27 | 8 | −2.2 | 1.7 |
| 14 | 6.6 | 8 | 15 | 26 | 8 | −2.3 | 1.8 |
| 15 | 6.0 | 7 | 14 | 28 | 9 | −2.3 | 1.9 |

As shown in table 2, the polyimide films produced in the manner according to example 1 to example 15 and estimated in the above mentioned manner have excellent properties such as a mean coefficient of linear expansion was 6 ppm/° C. or more to 30 ppm/° C. or less at 50 to 300° C.; a tensile modulus of at least 2.0 GPa; and a coefficient of hygroscopic expansion of 13 ppm or less. And also, the curling amount of “tape attached copper” according to the all the examples is −0.5 mm or less, and “tape completely etched” according to each example shows the value of 2.0 mm or less, which corresponds to a value to prevent the defect from the curling in manufacturing and mounting process.

### COMPARATIVE EXAMPLE 1

21.48 g of ODA and 11.06 g of PDA were dissolved into 407.5 g of DMF to be maintained at 0° C. Then 31.56 g of BPDA was slowly added the solution and stirred for 2 hours to completely dissolve BPDA. 14.04 g of PMDA was further added into the resultant solution and stirred for 1 hour. 13.83 g of BTDA was added to the resultant solution and stirred for 1 hour to form the polyamic acid solution having the properties such as a viscosity of 2800 poise at 23° C. and 18.5 wt % of solid content.

A polyimide film of 25 μm thickness and TAB tape were produced in the same method as example 1 excepting using the above obtained polyamic acid solution, and the mol % of the monomers and the properties of the polyimide film and TAB tape are shown in table 3 in the following.

And also, in the following <comparative example 2> to <comparative example 6>, the polyimide film of 25 μm thickness and TAB tape were produced the same manner as that of <example 1> except that each polyamic acid produced in each <comparative example> was used, and mol % of the monomers of each example, and the properties of each polyimide film and TAB tape are shown in table 3 in the following.

### COMPARATIVE EXAMPLE 2

19.20 g of ODA and 10.37 g of PDA were dissolved into 407.5 g of DMF to be maintained at 0° C. Then 28.21 g of BPDA was slowly added the solution and stirred for 2 hours to completely dissolve BPDA. 26.36 g of TMHQ was further added into the resultant solution and stirred for 1 hour, and 8.36 g of PMDA was added to the resultant solution and stirred for 1 hour to form the polyamic acid solution having the properties such as a viscosity of 2800 poise at 23° C. and 18.5 wt % of solid content. And the mol % of the monomers and the properties of the polyimide film and TAB tape are shown in table 3 in the following.

### COMPARATIVE EXAMPLE 3

19.92 g of ODA was dissolved into 407.5 g of DMF to be maintained at 0° C. Then 16.49 g of PMDA was slowly added the solution and stirred for 1 hour to completely dissolve PMDA. 10.76 g of PDA was dissolved and 17.57 g of BPDA was slowly added the solution and stirred for 2 hours to completely dissolve BPDA. 26.45 g of TMHQ was further added into the resultant solution and stirred for 1 hour, and 1.30 g of PMDA was added to the resultant solution and stirred for 1 hour to form the polyamic acid solution having the properties such as a viscosity of 3100 poise at 23° C. and 18.5 wt % of solid content. And the mol % of the monomers and the properties of the polyimide film and TAB tape are shown in table 3 in the following.

### COMPARATIVE EXAMPLE 4

44.27 of ODA was dissolved into 407.5 g of DMF to be maintained at 0° C. Then 48.23 g of PMDA was slowly added the solution and stirred for 2 hours to completely dissolve PMDA to form the polyamic acid solution having the properties such as a viscosity of 2800 poise at 23° C. and 18.5 wt % of solid content. And the mol % of the monomers and the properties of the polyimide film and TAB tape are shown in table 3 in the following.

### COMPARATIVE EXAMPLE 5

24.87 g of ODA and 13.43 g of PDA were dissolved into 407.5 g of DMF to be maintained at 0° C. Then 54.19 g of PMDA was slowly added the solution and stirred for 2 hours to completely dissolve PMDA to form the polyamic acid solution having the properties such as a viscosity of 2900 poise at 23° C. and 18.5 wt % of solid content. And the mol % of the monomers and the properties of the polyimide film and TAB tape are shown in table 3 in the following.

### COMPARATIVE EXAMPLE 6

26.19 g of ODA and 14.14 g of PDA were dissolved into 489 g of DMF to be maintained at 0° C. Then 42.14 g of BTDA was slowly added the solution and stirred for 1 hour, and 28.53 g of PMDA was slowly added the solution and stirred for 2 hours to completely dissolve PMDA to form the polyamic acid solution having the properties such as a viscosity of 3000 poise at 23° C. and 18.5 wt % of solid content. And the mol % of the monomers and the properties of the polyimide film and TAB tape are shown in table 3 in the following.

TABLE 3

| | Diamine | | | | | | | | | | |
|---|---|---|---|---|---|---|---|---|---|---|---|
| | Com- | | | | | | | | | Curling | |
| | pound | | Acid anhydrides | | | | Tensile | CTE | | (mm) | |
| Comp. | (mol %) | | (mol %) | | | | modulus | (ppm) | CHE | Copper | Completely |
| Exams. | ODA | PDA | TMHQ | BTDA | PMDA | BPDA | (GPa) | 100-200° C. | (ppm) | Attached | Etched |
| 1 | 50 | 50 | | 20 | 30 | 50 | 5.6 | 19 | 14 | 1.0 | 1.7 |
| 2 | 50 | 50 | 30 | — | 20 | 50 | Cannot measure characteristic of film due to | | | | |
| | | | | | | | fusion of the film during plasticity | | | | |
| 3 | 50 | 50 | 29 | — | 41 | 30 | Cannot measure characteristic of film due to | | | | |
| | | | | | | | promulgation of the film during plasticity | | | | |
| 4 | 100 | — | — | — | 100 | — | 3.1 | 32 | 12 | −3.2 | 4.5 |
| 5 | 50 | 50 | — | — | 100 | — | 5.7 | 13 | 15 | −2.7 | 1.6 |
| 6 | 50 | 50 | — | 50 | 50 | — | 5.7 | 13 | 15 | −2.7 | 1.6 |

(Reference)
ODA: 4,4′-Oxydianiline, PDA: p-phenylenediamine.
TMHQ: p-phenylene bis (trimellitic acid monoester anhydride).
BTDA: 3,3′,4,4′-benzophenone tetracarboxylic dianhydride
PMDA: pyromellitic dianhydride.
BPDA: 3,3′,4,4′-biphenyltetracarboxylic dianhydride

As shown in table 3, the polyimide films manufactured by the manner according to comparative example 1 to comparative example 6 and estimated in the above mentioned manner have at least one degraded property among a mean coefficient of linear expansion, a tensile modulus, and a coefficient of hygroscopic expansion. And also, the curling amount of “tape attached copper” according to comparative example 5 and 6 is −0.55 mm or less, but the property of a coefficient of hygroscopic expansion (CHE) shows a value of more than 13 ppm. And “tape completely etched” according to comparative example 4 shows the value of 3.0 mm or more, which shows the degraded property compared to the polyimide of the present invention.

As described in the above, the polyimide film of the present invention may be obtained from the polyamic acid synthesized with mainly an aromatic diamine and an aromatic tetracarboxylic dianhydride, and an aromatic tetracarboxylic dianhydride may include 4,4′-oxydiphthalic anhydride while an aromatic diamine may include the p-phenylenediamine. The polyimide film of the present invention has the properties such as a mean coefficient of linear expansion was 6 ppm/° C. or more to 30 ppm/° C. or less at 50 to 300° C.; a tensile modulus of at least 2.0 GPa; and a coefficient of hygroscopic expansion was 13 ppm or less. Hence the polyimide film of the present invention has the coefficient of linear expansion and the tensile modulus corresponding to disappearance of the curling or twisting and has the coefficient of hygroscopic expansion corresponding to disappearance of the curling or twisting due to the dimensional change by a moisture-absorption. In the result, the curling or twisting to happen during manufacturing process of the FPC or TAB tape used in various electronic devices and to be the cause of the mounting inferiority can be avoided effectively.

The specific embodiments or examples illustrated in the specification is given only for clear understanding of the present invention, therefore the scope of the present invention should not be limited to the embodiments or examples. Various modification and alternation can be made within the spirit and the scope of the following claims by the skilled in this art.

What is claimed is:

1. A polyimide film produced from a polyamic acid, said polyamic acid being prepared by reacting monomer components consisting of:
(i) an acid anhydride, and
(ii) diamine compounds,
wherein the acid anhydride is pyromellitic dianhydride,
wherein the diamine compounds comprise p-phenylenediamine, and at least one diamine compound selected from the group consisting a diamine compound including an ether linkage between an H₂N—C bond and another H₂N—C bond in the molecule, a diamine compound including a methylene linkage between an H₂N—C bond and another H₂N—C bond in the molecule, and a diamine compound having a structure wherein an H₂N—C bond and another H₂N—C bond are not linearly arranged; and
wherein the polyimide film has an average coefficient of linear expansion in the range of 50° C. to 300° C. of 6 to 30 ppm, a tensile modulus of 2.0 GPa or more, and a coefficient of hygroscopic expansion of 13 ppm or less.

2. The polyimide film according to claim 1, wherein the acid anhydride is selected from the group of pryomellitic dianhydride, a mixture of pyromellitic dianhydride and 3,3′,4,4′-benzophenone tetracarboxylic dianhydride, and a mixture of pyromellitic dianhydride and 3,3′,4,4′-biphenyltetracarboxylic dianhydride.

3. The polyimide film according to claim 1, wherein the diamine compounds comprise p-phenylenediamine and 4,4′-diaminodiphenylmethane,

4. The polyimide film according to claim 1, wherein the diamine compounds comprise p-phenylenediamine and 4,4′-oxydianiline.

5. The polyimide film according to claim 1, wherein the amount of p-phenylenediamine is 10 mol % to 70 mol % based on the total diamine compounds.

6. The polyimide film according to claim 1, wherein the amount of p-phenylenediamine is 20 mol % to 60 mol % based on the total diamine compounds.

7. The polyimide film according to claim 3, wherein the amount of p-phenylenediamine is 10 mol % to 70 mol % based on the total diamine compound.

8. The polyimide film according to claim 4, wherein the amount of p-phenylenediamine is 10 mol % to 70 mol % based on the total diamine compound.

9. The polyimide film according to claim 3, wherein the amount of p-phenylenediamine is 20 mol % to 60 mol % based on the total diamine compound.

10. The polyimide film according to claim 4, wherein the amount of p-phenylenediamine is 20 mol % to 60 mol % based on the total diamine compound.

11. A TAB tape comprising
the polyimide film according to claim 1;
an adhesive layer provided on the polyimide film; and
a protective layer provided on the adhesive layer.

12. A flexible printed circuits board comprising
the polyimide film according to claim 1; and
a metallic conductive layer laminated on at least one side of the polyimide.

13. A polyimide film produced from a polyamic acid, said polyamic acid being prepared by reacting monomer components consisting of:
(i) an acid anhydride, and
(ii) diamine compounds,
wherein the acid anhydride comprises pyromellitic dianhydride,
wherein the diamine compounds comprise p-phenylene diamine, and at least one diamine compound selected from the group consisting a diamine compound including an ether linkage between an H₂N—C bond and another H₂N—C bond in the molecule, a diamine compound including a methylene linkage between an H₂N—C bond and another H₂N—C bond in the molecule, and a diamine compound having a structure wherein an H₂N—C bond and another H₂N—C bond are not linearly arranged; and
wherein the polyimide film has an average coefficient of linear expansion in the range of 50° C. to 300° C. of 6 to 30 ppm, a tensile modulus of 5.4 GPa or more, and a coefficient of hygroscopic expansion of 9 ppm or less.

14. The polyimide film according to claim 13, wherein the acid anhydride further comprises 3,3′,4,4′-benzophenone tetracarboxylic dianhydride, 3,3′,4,4′-biphenyltetracarboxylic dianhydride, or 4,4′-oxydiphthalic anhydride.

15. The polyimide film according to claim 13, wherein the diamine compounds comprise:
p-phenylenediamine; and
4,4′-diaminodiphenylmethane or 4,4′-oxydianiline.

16. The polyimide film according to claim 13, wherein the amount of p-phenylenediamine is 20 mol % to 60 mol % based on the total diamine compounds.

17. The polyimide film according to claim 15, wherein the amount of p-phenylenediamine is 20 mol % to 60 mol % based on the total diamine compounds.
